(19) United States
(12) Patent Application Publication
(10) Pub. No.: US 2024/0373545 A1
(43) Pub. Date: Nov. 7, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Hsiang-Hua HUANG, Taichung City (TW); I-Tang LIU, Taichung City (TW); Mu-Hsuan CHAN, Taichung City (TW)

(73) Assignee: SILICONWARE PRECISION INDUSTRIES CO., LTD., Taichung City (TW)

(21) Appl. No.: 18/639,423

(22) Filed: Apr. 18, 2024

(30) Foreign Application Priority Data
May 5, 2023 (TW) 112116850

(51) Int. Cl. H05K 1/02; H01L 23/00; H01L 25/065; H05K 3/34

(52) U.S. Cl. CPC H05K 1/0213; H01L 25/0655; H05K 3/34; H01L 24/16; H01L 24/32; H01L 24/73; H01L 2224/16225; H01L 2224/32225; H01L 2224/73204; H01L 2924/1815; H05K 2201/0367

(57) ABSTRACT

An electronic package and a manufacturing method thereof are provided, in which support members are disposed on a carrier structure having a plurality of electrical contact pads, and a conductive element is bonded on each of the electrical contact pads, and an electronic module is disposed on the carrier structure via the conductive elements, so that the support members contact and support the electronic module to prevent the electronic module from warping.

### BACKGROUND

### 1. Technical Field

The present disclosure relates to a semiconductor packaging process, and more particularly, to an electronic package and a manufacturing method thereof.

### 2. Description of Related Art

With the vigorous development of the electronics industry, electronic products are gradually developing towards multi-functional and high-performance trends. There are many technologies currently used in the field of chip packaging, such as chip scale package (CSP), direct chip attached (DCA), multi-chip module (MCM), and other flip-chip package modules.

FIG. 1 is a schematic cross-sectional view of a conventional semiconductor package 1. First, an electronic module 1a and a package substrate 16 having a plurality of bump-shaped solder materials 17 are provided, wherein the electronic module 1a includes a circuit structure 10, a plurality of semiconductor chips 11 disposed and spaced apart on the upper side of the circuit structure 10, and an encapsulant 14 formed on the circuit structure 10 to cover the semiconductor chips 11, wherein the semiconductor chips 11 are bonded to the circuit structure 10 in a flip-chip manner via a plurality of conductive bumps 12, and the conductive bumps 12 are covered with an underfill 13. Next, a plurality of copper pillars 15 are arranged on the lower side of the circuit structure 10, so that the circuit structure 10 is bonded to the solder materials 17 of the package substrate 16 via the copper pillars 15. Thereafter, the solder materials 17 are reflowed to fix the electronic module 1a on the package substrate 16.

However, in the conventional semiconductor package 1, the electronic module 1a is prone to warping (as shown by the outline of dotted lines in FIG. 1) at high temperatures (such as during the process of reflowing the solder materials 17), so that the middle area of the electronic module 1a will be lower than the peripheral area of the electronic module 1a when the electronic module 1a and the package substrate 16 are connected to each other, resulting in that the solder materials 17 on two adjacent copper pillars 15 in the middle area of the electronic module 1a bridge each other and cause a short circuit, even non-wetting problems occur between the copper pillars 15 and the solder materials 17 in the peripheral area of the electronic module 1a.

Therefore, how to overcome the above-mentioned problems of the prior art has become an urgent issue to be solved.

### SUMMARY

In view of the various deficiencies of the prior art, the present disclosure provides an electronic package, which comprises: a carrier structure having a plurality of electrical contact pads, wherein each of the electrical contact pads is bonded to a conductive element; a plurality of support members disposed on the carrier structure; and an electronic module disposed on the carrier structure via the conductive elements, wherein the support members contact and support the electronic module.

The present disclosure also provides a method of manufacturing an electronic package, the method comprises: providing a carrier structure having a plurality of electrical contact pads and an electronic module, wherein each of the electrical contact pads is bonded to a conductive element, and support members are disposed on the carrier structure; and disposing an electronic module on the carrier structure via the conductive elements in a hot-pressing manner, so that the support members contact and support the electronic module.

In the aforementioned electronic package and method, the support members are insulators and are evenly distributed on the carrier structure or non-evenly distributed on the carrier structure.

In the aforementioned electronic package and method, a quantity distribution of the support members is reduced according to an increase in a quantity of the electrical contact pads.

In the aforementioned electronic package and method, a distance between adjacent two of the plurality of electrical contact pads is at least 40 microns.

In the aforementioned electronic package and method, a width of each of the support members is at least 70% of a distance between adjacent two of the plurality of electrical contact pads.

In the aforementioned electronic package and method, the electronic module is bonded to the conductive elements via conductors and solder materials, and a height of the support member is less than a total height of the conductor, the solder material and the conductive element. For example, a height difference between the height of the support member and the total height of the conductor, the solder material and the conductive element is 10 microns.

In the aforementioned electronic package and method, a quantity of the support members is the same as or greater than half of a quantity of the conductive elements.

In the aforementioned electronic package and method, the electronic module includes a plurality of electronic elements spaced apart. For example, a middle area of the electronic module corresponds to a separation space between adjacent two of the plurality of electronic elements.

As can be seen from the above, in the electronic package and the manufacturing method thereof of the present disclosure, the support members contact and support the electronic module to prevent the partial area of the electronic module from deforming. Therefore, compared with the prior art, the electronic module will not warp at high temperatures, so as to avoid the problem of short circuit caused by the bridging of two adjacent conductive elements corresponding to the partial area of the electronic module, and avoid the problem of non-wetting of the conductive elements corresponding to another area of the electronic module, thereby effectively improving the reliability of the electronic package.

### BRIEF DESCRIPTION OF THE DRAWINGS

FIG. 1 is a schematic cross-sectional view of a conventional semiconductor package.

FIG. 2A to FIG. 2C are schematic cross-sectional views illustrating a manufacturing method of an electronic package according to the present disclosure.

FIG. 3 is a schematic top view of another embodiment of FIG. 2A.

FIG. 4 is a schematic top view of yet another embodiment of FIG. 2A.

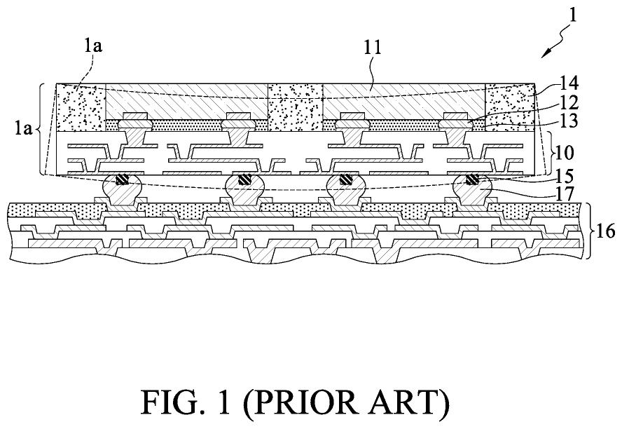

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

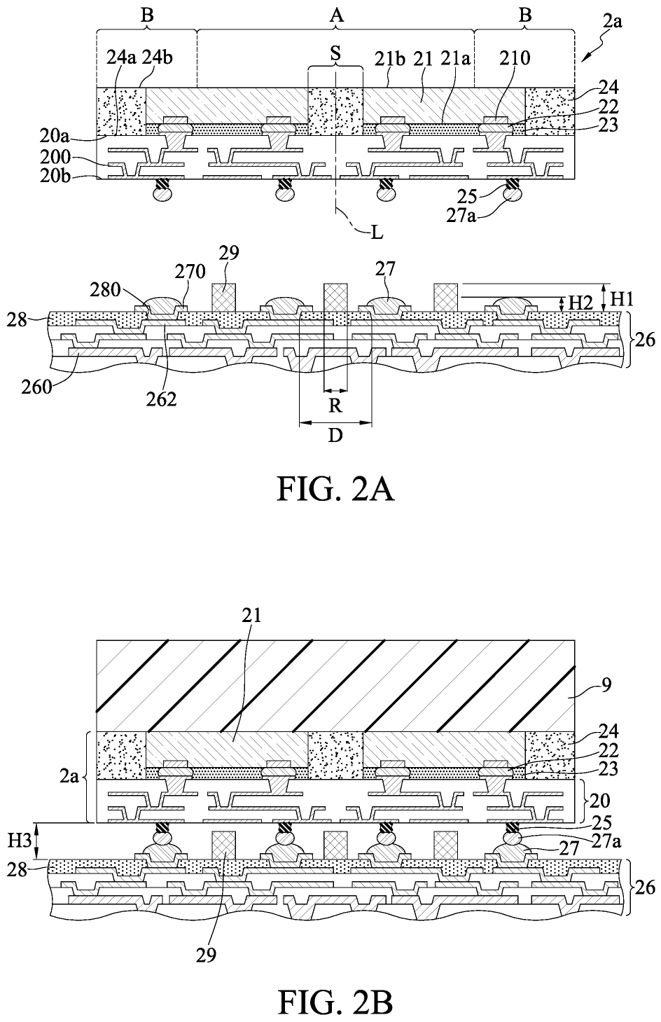

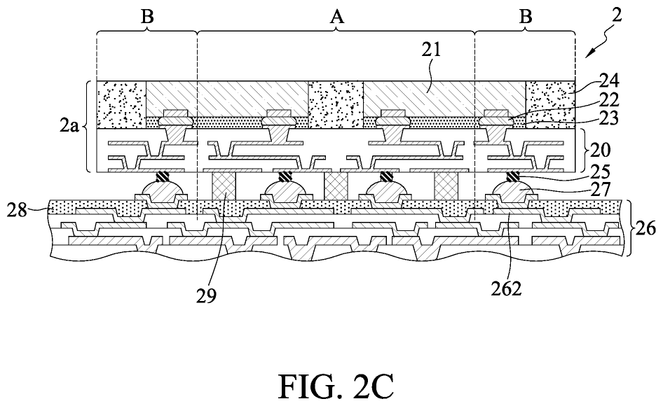

FIG. 2A to FIG. 2C are schematic cross-sectional views illustrating a manufacturing method of an electronic package 2 according to the present disclosure.

As shown in FIG. 2A, an electronic module 2a and a carrier structure 26 are provided, wherein the electronic module 2a includes a substrate structure 20, a plurality of electronic elements 21 disposed and spaced apart on the substrate structure 20, and an encapsulation layer 24 formed on the substrate structure 20 and covering the electronic elements 21.

The substrate structure 20 can be a circuit structure with a core layer or a circuit structure without a core layer (coreless), and the substrate structure 20 is constructed by forming a plurality of circuit layers 200, such as redistribution layers (RDLs), on a dielectric material.

In one embodiment, the substrate structure 20 is a coreless circuit structure and is defined with a first side 20a and a second side 20b opposing the first side 20a. However, in other embodiments, the substrate structure 20 can also be a semiconductor substrate with a plurality of through-silicon vias (TSVs) to serve as a through-silicon interposer (TSI).

Each of the electronic elements 21 can be an active element, a passive element, a package structure, or a combination thereof, and each of the electronic elements 21 is disposed on the first side 20a of the substrate structure 20, wherein the active element is such as a semiconductor chip, and the passive element is such as a resistor, a capacitor, or an inductor.

In one embodiment, each of the electronic elements 21 is a semiconductor chip and has an active surface 21a and an inactive surface 21b opposing the active surface 21a, wherein there are a plurality of electrode pads 210 on the active surface 21a, and conductive bump 22 is formed on each of the electrode pads 210, so that the conductive bumps 22 are electrically connected to the circuit layer 200 on the first side 20a of the substrate structure 20 in a flip-chip manner, and a cladding layer 23 is formed between the active surface 21a and the first side 20a, so that the cladding layer 23 covers the conductive bumps 22.

Furthermore, each of the conductive bumps 22 is a metal pillar (such as a copper pillar), solder material, or a combination thereof, and the cladding layer 23 is an underfill or a non-conductive film (NCF), so that the encapsulation layer 24 covers the cladding layer 23.

In addition, although the electronic elements 21 are all of the same type (i.e., active elements), the internal structures of the electronic elements 21 may be the same or different. For example, one of the electronic elements 21 (active element) is an application-specific integrated circuit (ASIC) type semiconductor chip, and another one of the electronic elements 21 is a control chip or a high bandwidth memory (HBM) type chip.

In addition, the electronic module 2a is defined with a middle area A and a peripheral area B located outside the middle area A, and the middle area A corresponds to a separation space S between two adjacent electronic elements 21. For example, a center line L of the separation space S is a center line L of the electronic module 2a.

The encapsulation layer 24 can be made of an insulating material, such as polyimide (PI), dry film, epoxy (epoxy resin), molding compound, or other suitable materials. The encapsulation layer 24 has a first surface 24a and a second surface 24b opposing the first surface 24a, and the first surface 24a of the encapsulation layer 24 is bonded onto the first side 20a of the substrate structure 20.

In one embodiment, the encapsulation layer 24 is formed on the substrate structure 20 by lamination or molding.

Furthermore, the material for forming the encapsulation layer 24 is different from the material for forming the cladding layer 23. For instance, the Young's modulus of the encapsulation layer 24 is greater than the Young's modulus of the cladding layer 23.

In addition, the inactive surfaces 21b of the electronic elements 21 can be made coplanar with the second surface 24b of the encapsulation layer 24 via a leveling process or a thinning process, so that the inactive surfaces 21b of the electronic elements 21 are exposed from the encapsulation layer 24. For example, when the encapsulation layer 24 is formed on the substrate structure 20, the encapsulation layer 24 covers the inactive surfaces 21b of the electronic elements 21, and then part of the material of the encapsulation layer 24 is removed by grinding or cutting (part of the material of the inactive surfaces 21b of the electronic elements 21 can also be removed at the same time according to needs), so that the inactive surfaces 21b of the electronic elements 21 are flush with the second surface 24b of the encapsulation layer 24.

In addition, after forming the encapsulation layer 24, a plurality of conductors 25 can be formed on the second side 20b of the substrate structure 20. For example, each of the conductors 25 is a metal pillar (such as a copper pillar), and the end portion of each of the conductors 25 can be bonded to a solder material 27a according to requirements.

The carrier structure 26 is a circuit board and includes at least one insulating layer and at least one circuit layer 260 formed on the insulating layer, wherein an insulating protective layer 28 is formed on the outermost insulating layer, and at least one support member 29 is formed on the insulating protective layer 28.

In one embodiment, the circuit layer 260 is applied with redistribution layer (RDL) specification, wherein the material for forming the circuit layer 260 is copper, and the material for forming the insulating layer is such as polybenzoxazole (PBO), polyimide (PI), prepreg (PP), or other dielectric materials.

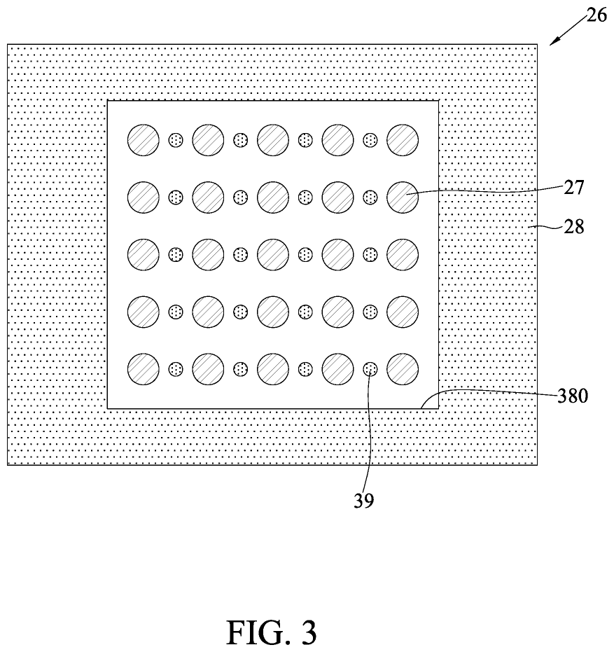

Furthermore, the insulating protective layer 28 can be a dielectric layer or a solder-resist layer made of such as solder mask (e.g., green solder mask), graphite (e.g., ink), and the like, wherein a plurality of openings 280 can be formed in the insulating protective layer 28, so that the outermost circuit layer 260 is exposed from each of the openings 280 to serve as electrical contact pads 262 for bonding to conductive elements 27 such as solder materials. Alternatively, the insulating protective layer 28 may form an opening 380 that exposes each of the electrical contact pads 262 (or the conductive elements 27), as shown in FIG. 3. It should be understood that an under bump metallurgy (UBM) layer 270 can be formed on the electrical contact pads 262 to facilitate bonding to the conductive elements 27.

In addition, a distance D between two adjacent electrical contact pads 262 is at least 40 microns (μm), and a width R (diameter) of each of the support members 29 is at least 70% of the distance D between two adjacent electrical contact pads 262 (R≥0.7D).

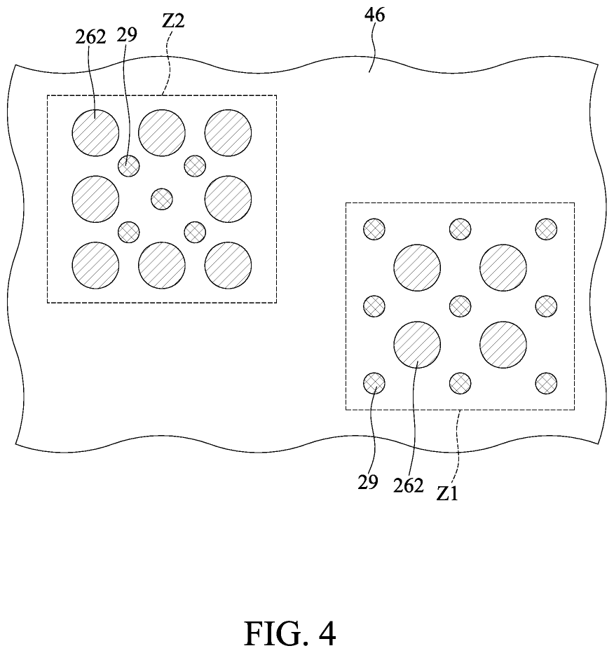

In addition, the support members 29 are insulators and can be evenly distributed (support members 39 shown in FIG. 3) or non-evenly distributed (the support members 29 shown in FIG. 4) on the carrier structure 26. For example, the support members 39 and the insulating protective layer 28 are integrally formed, as shown in FIG. 3, so that the two materials are the same.

As shown in FIG. 2B and FIG. 2C, each of the conductors 25 of the electronic module 2a is disposed on the conductive element 27 of each of the electrical contact pads 262 of the carrier structure 26 via the solder material 27a, so that the support members 29 contact and support the electronic module 2a. Then, a hot-pressing member 9 is used to hot press the electronic module 2a so as to reflow the solder materials 27a and the conductive elements 27, so that the conductive elements 27 are bonded to the conductors 25.

In one embodiment, the quantity of the support members 29 (25 as shown in FIG. 3) is the same as or greater than half (that is, the same as or greater than 13) of the quantity of the conductive elements 27 (25 as shown in FIG. 3), so as to support the electronic module 2a.

Furthermore, a height H1 of the support member 29 relative to the carrier structure 26 is greater than or equal to a height H2 of the conductive element 27 relative to the carrier structure 26, as shown in FIG. 2A, and the height H1 of the support member 29 relative to the carrier structure 26 is less than a total height H3 of the conductor 25, the solder material 27a and the conductive element 27, as shown in FIG. 2B, so as to support the electronic module 2a. For example, a height difference between the height H1 of the support member 29 and the total height H3 is about 10 microns (μm).

In addition, the arrangement position and quantity distribution of the support members 29 are reduced according to the increase in the quantity of the electrical contact pads 262. For example, in a carrier structure 46 shown in FIG. 4, more support members 29 are arranged in an area Z1 where the electrical contact pads 262 are arranged with a smaller quantity, and fewer support members 29 are arranged in an area Z2 where the electrical contact pads 262 are arranged with a larger quantity, so as to support the electronic module 2a.

Next, the hot-pressing member 9 is removed to obtain the electronic package 2.

Therefore, in the manufacturing method of the present disclosure, via the arrangement of the support members 29, 39, when the hot-pressing member 9 exerts downward pressure, the support members 29, 39 can support the electronic module 2a (such as the middle area A) to prevent a partial area of the electronic module 2a from deforming (such as the lowering of the middle area A). Therefore, compared with the prior art, the electronic module 2a will not warp at high temperatures (such as during the process of reflowing the solder materials 27a and the conductive elements 27). Therefore, when the electronic module 2a and the carrier structure 26 are connected, the problem of short circuit caused by the bridging of two adjacent conductive elements 27 corresponding to the partial area (such as the middle area A) of the electronic module 2a can be avoided, and the problem of non-wetting of the conductors 25 and the conductive elements 27 corresponding to another area (such as the peripheral area B) of the electronic module 2a can be avoided.

The present disclosure further provides an electronic package 2, which comprises: a carrier structure 26, 46, at least one support member 29, 39 and an electronic module 2a.

The carrier structure 26, 46 has a plurality of electrical contact pads 262, and a conductive element 27 is bonded on each of the electrical contact pads 262.

The support members 29, 39 are disposed on the carrier structure 26, 46.

The electronic module 2a is disposed on the carrier structure 26, 46 via a plurality of the conductive elements 27, and the support members 29, 39 contact and support the electronic module 2a.

In one embodiment, the support members 29, 39 are insulators and are evenly distributed on the carrier structure 26 or non-evenly distributed on the carrier structure 46.

In one embodiment, the quantity distribution of the support members 29, 39 is reduced according to the increase in the quantity of the electrical contact pads 262.

In one embodiment, a distance D between two adjacent electrical contact pads 262 is at least 40 microns.

In one embodiment, a width R of each of the support members 29 is at least 70% of the distance D between adjacent two of the plurality of electrical contact pads 262.

In one embodiment, the electronic module 2a is bonded to the conductive elements 27 via the conductors 25 and the solder materials 27a, and a height H1 of the support member 29 is less than a total height H3 of the conductor 25, the solder material 27a and the conductive element 27. For example, the height difference between the height H1 of the support member 29 and the total height H3 of the conductor 25, the solder material 27a and the conductive element 27 is 10 microns.

In one embodiment, the quantity of the support members 29 is the same as or greater than half of the quantity of the conductive elements 27.

In one embodiment, the electronic module 2a includes a plurality of electronic elements 21 spaced apart. For example, a middle area A of the electronic module 2a corresponds to a separation space S between two adjacent electronic elements 21.

To sum up, in the electronic package and the manufacturing method thereof of the present disclosure, via the arrangement of the support members, the support members can support the middle area of the electronic module to prevent the partial area of the electronic module from deforming. Therefore, the electronic module will not warp at high temperatures, thereby avoiding the problem of short circuit caused by two adjacent conductive elements bridging each other, and avoiding the problem of non-wetting of some conductive elements.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a plurality of electrical contact pads, wherein each of the electrical contact pads is bonded to a conductive element;
a plurality of support members disposed on the carrier structure; and
an electronic module disposed on the carrier structure via the conductive elements, wherein the support members contact and support the electronic module.

2. The electronic package of claim 1, wherein the support members are insulators and are evenly distributed on the carrier structure or non-evenly distributed on the carrier structure.

3. The electronic package of claim 1, wherein a quantity distribution of the support members is reduced according to an increase in a quantity of the electrical contact pads.

4. The electronic package of claim 1, wherein a distance between adjacent two of the plurality of electrical contact pads is at least 40 microns.

5. The electronic package of claim 1, wherein a width of each of the support members is at least 70% of a distance between adjacent two of the plurality of electrical contact pads.

6. The electronic package of claim 1, wherein the electronic module is bonded to the conductive elements via conductors and solder materials, and a height of the support member is less than a total height of the conductor, the solder material and the conductive element.

7. The electronic package of claim 6, wherein a height difference between the height of the support member and the total height of the conductor, the solder material and the conductive element is 10 microns.

8. The electronic package of claim 1, wherein a quantity of the support members is the same as or greater than half of a quantity of the conductive elements.

9. The electronic package of claim 1, wherein the electronic module includes a plurality of electronic elements spaced apart.

10. The electronic package of claim 9, wherein a middle area of the electronic module corresponds to a separation space between adjacent two of the plurality of electronic elements.

11. A method of manufacturing an electronic package, comprising:
providing a carrier structure having a plurality of electrical contact pads and an electronic module, wherein each of the electrical contact pads is bonded to a conductive element, and support members are disposed on the carrier structure; and
disposing an electronic module on the carrier structure via the conductive elements in a hot-pressing manner, so that the support members contact and support the electronic module.

12. The method of claim 11, wherein the support members are insulators and are evenly distributed on the carrier structure or non-evenly distributed on the carrier structure.

13. The method of claim 11, wherein a quantity distribution of the support members is reduced according to an increase in a quantity of the electrical contact pads.

14. The method of claim 11, wherein a distance between adjacent two of the plurality of electrical contact pads is at least 40 microns.

15. The method of claim 11, wherein a width of each of the support members is at least 70% of a distance between adjacent two of the plurality of electrical contact pads.

16. The method of claim 11, wherein the electronic module is bonded to the conductive elements via conductors and solder materials, and a height of the support member is less than a total height of the conductor, the solder material and the conductive element.

17. The method of claim 16, wherein a height difference between the height of the support member and the total height of the conductor, the solder material and the conductive element is 10 microns.

18. The method of claim 11, wherein a quantity of the support members is the same as or greater than half of a quantity of the conductive elements.

19. The method of claim 11, wherein the electronic module includes a plurality of electronic elements spaced apart.

20. The method of claim 19, wherein a middle area of the electronic module corresponds to a separation space between adjacent two of the plurality of electronic elements.
